(19) United States
(12) Patent Application Publication
(10) Pub. No.: US 2021/0243858 A1
(43) Pub. Date: Aug. 5, 2021

(54) MULTI-LAYERED RADIATION LIGHT SOURCE

(71) Applicant: NATIONAL INSTITUTE FOR MATERIALS SCIENCE, Ibaraki (JP)

(72) Inventors: Tadaaki NAGAO, Ibaraki (JP); Tung Anh DOAN, Ibaraki (JP); Duy Thang DAO, Ibaraki (JP); Satoshi ISHII, Ibaraki (JP)

(73) Assignee: NATIONAL INSTITUTE FOR MATERIALS SCIENCE, Ibaraki (JP)

(21) Appl. No.: 17/052,563

(22) PCT Filed: May 24, 2019
(86) PCT No.: PCT/JP2019/020572

§ 371 Date: Nov. 3, 2020

(30) Foreign Application Priority Data
May 25, 2018 (JP) 2018-100713
Apr. 5, 2019 (JP) 2019-072426

(51) Int. Cl. H05B 39/00; H05B 39/04; H05B 3/00

(52) U.S. Cl. CPC H05B 39/00; H05B 3/0033; H05B 39/04

(57) ABSTRACT

Provided is a radiation light source that enables adjustment of infrared radiation to a significantly narrow band. A plasmonic reflector layer consisting of a plasmonic material, a resonator layer consisting of an insulator, and a partially reflecting layer are alternately laminated in this order to form a multi-layered radiation light source, wherein the partially reflecting layer are selected from any one of a free interface, an ultrathin-film metallic layer, and a distributed reflector layer having a structure in which layers having different refractive indexes are alternately laminated. When a material with high-temperature resistance such as SiC is used in the outermost layer of the distributed reflector layer, the multi-layered radiation light source can operate at high temperatures of 550° C. and higher.

### TECHNICAL FIELD

The present invention relates to a radiation light source which has a simple structure with multi-layered, or laminated conductors and insulator materials and enables low-cost and large-area production and has wavelength controllability such as band narrowing effect and is preferable for, for example, infrared processing. In addition, when a high-temperature resistant material is employed as at least part of the conductors or the insulator materials as needed, the radiation light source can be made to stably operate at high temperatures for a long period of time.

### BACKGROUND ART

Each substance has a particular absorption spectrum. When a substance is irradiated with light having a specific wavelength at which the substance shows high absorption, it is possible, for example, to dry, anneal, or form the substance with high efficiency. Furthermore, when gases are irradiated with a narrowband light corresponding to an absorption wavelength particular to a gas molecule, it is possible to monitor the abundance of the gas molecule based on variation of absorption which depends on the gases present in a light path.

The former example may be applied to applications to roll-to-roll printing and coating or resin drying. For example, when a solvent is irradiated with infrared light having a wavelength corresponding to an absorption wavelength of the solvent, it is possible to save energy and dry the solvent at high speed while preventing unwanted temperature rise. What is more, the former example prevents overheat of a product or the interior of a processing device, which enables molding, reactions, and processing with high accuracy while preventing deterioration of the product and the device.

The latter example may be applied to applications to, for example, non-dispersive infrared absorption (NDIR). When a target sample gas is irradiated with infrared light having an adequately narrow band according to an infrared absorption wavelength particular to the gas, it is possible to detect the gas of interest with high selectivity. The narrower the wavelength width of infrared light to be emitted, the more accurately and selectively the absorption of gas molecules can be measured, which enhances the identification accuracy of molecular species and the measurement sensitivity. FIG. 1 shows examples of structures and radiation spectra of devices in the related art.

As a wavelength-selective infrared radiation light source, there is disclosed a structure that emits infrared light having a specific wavelength by heating a three-dimensional uneven structure (Non-Patent Literature 1, Patent Literatures 1 and 2) or a two-dimensional microfabricated metal-insulator-metal structure (MIM structure) (Patent Literature 3). A diffraction grating device having the three-dimensional uneven structure emits light with a narrow band but has a complicated structure and is not suitable for large-area production. Such a device also has problems that a direction of radiation is not always perpendicular to a heater surface and that its wavelength fluctuates widely depending on radiation angles. In regard to a device having the two-dimensional patterned MIM structure, a half width is about 10% of a radiation wavelength at its narrowest, which is unsuitable for applications that require high selectivity of wavelength. Especially for use as a gas sensor, such a device has too wide a radiation wavelength width compared to absorption bandwidths of gas molecules. Therefore, it is difficult to separate a signal of a target gas molecule from signals of other gas molecules.

On the other hand, there is disclosed a narrowband radiation light source having a resonant structure between a multi-layered distributed Bragg reflector and plasmonic reflector layer (Non-Patent Literature 2). There are other similar structures disclosed. However, to put narrowband radiation light sources into practical applications, the present inventors have specifically studied radiation light sources as one disclosed in Non-Patent Literature 2 and have found that laminated Si on Au or Ag causes exfoliation at about 300° C. due to interlayer adhesiveness and thermal expansion, which hinders practical applications of narrowband radiation light sources. The inventors have also found that using Ti or Cr as an adhesive layer enhances adhesiveness but deteriorates plasmonic properties, leading to deterioration of radiation properties. Furthermore, the inventors have also found that disposing a metal in the outermost layer on the side close to the air (Non-Patent Literature 3) or disposing an easily-oxidizable semiconductor layer such as Si or Ge in the outermost layer provides no assurance of prolonged stable operation because high-temperature operation in the air causes a change in physical properties of the material and a radiation wavelength changes depending on operating temperatures. Still further, as a result of further study, the inventors have found that the use of a doped semiconductor material such as Si, Ge, and ZnO or the use of a narrow-gap semiconductor as a constituent material changes optical properties in the mid- and far-infrared regions due to carrier generation by thermal excitation, which may change an infrared radiation spectrum along with temperature rise.

### SUMMARY OF INVENTION

### Technical Problem

An object of the present invention is to provide a radiation light source device which can adjust a bandwidth and, if desired, set to have a half width about single digit or double digits narrower than a radiation wavelength or an even narrower half width and to achieve the radiation light source device as a simple and large-area radiator with a simple multi-layered structure without three- or two-dimensional nano/micro patterning. Another object of the present invention is to enable stable and long-life operation of the device at high temperatures by appropriating selecting materials.

### Solution to Problem

According to an aspect of the present invention, there is provided a multi-layered radiation light source including: a plasmonic reflector layer; a resonator layer consisting of an insulator layer, said resonator layer being adjacent to the plasmonic reflector layer; and a distributed reflector layer having a structure in which a plurality of types of insulator layers having different refractive indexes are alternately laminated, said distributed reflector layer being arranged on the resonator layer on the opposite side of the plasmonic reflector layer, in which the multi-layered radiation light source emits infrared light from the distributed reflector layer to the outside by heating the plasmonic reflector layer.

At least one of the plurality of types of insulator layers which constitutes the distributed reflector layer may have high-temperature resistance.

According to another aspect of the present invention, there is provided a multi-layered radiation light source including: a metallic total reflecting layer; a resonator layer consisting of an insulator layer, said resonator layer is adjacent to the metallic total reflecting layer; and a partially reflecting layer being configured to reflect part of incident light, said partially reflecting layer being arranged on the resonator layer on the opposite side of the metallic total reflecting layer, in which a metal in the metallic total reflecting layer is an optical metallic material having a complex permittivity with a negative real part at a wavelength to be used, and the multi-layered radiation light source emits infrared light from the partially reflecting layer to the outside by heating the metallic total reflecting layer.

The partially reflecting layer may be an interface between the resonator layer and an external space formed by a surface of the resonator layer on the opposite side of the total reflecting layer.

The partially reflecting layer may be a metallic layer configured to reflect part of incident light.

The metallic layer that reflects part of the incident light may have high-temperature resistance.

The partially reflecting layer may be a distributed reflector layer having a structure in which a plurality of types of insulator layers having different refractive indexes are alternately laminated.

At least one of the plurality of types of insulator layers may have high-temperature resistance.

The insulator layer which constitutes the resonator layer and the insulator layer having a low refractive index in the distributed reflector layer may be composed of the same material.

Alternatively, the insulator layer which constitutes the resonator layer and the insulator layer having a low refractive index in the distributed reflector layer may be composed of different materials.

In the plurality of types of insulator layers which constitute the distributed reflector layer, the insulator layer having a high refractive index may have a refractive index 1.3 times or more a refractive index of the insulator layer having a low refractive index.

In the plurality of types of insulator layers which constitute the distributed reflector layer, at least the insulator layer in contact with the air may be composed of an oxide or SiC.

In the distributed reflector layer, the insulator layer having a low refractive index may be a material selected from the group consisting of SiO₂, Al₂O₃, and Si₃N₄, and the insulator layer having the high refractive index may be a material selected from the group consisting of Si, Ge, SiC, Ta₂O₅, Nb₂O₅, and HfO₂.

The plasmonic reflector layer or the metallic total reflecting layer may have high-temperature resistance.

The plasmonic reflector layer or the metallic total reflecting layer may be selected from the group consisting of LaB₆, Au, W, Mo, Cu alloy, Al alloy, and Ni alloy, having a complex permittivity with a negative real part, and from the group consisting of metallic nitride, metallic carbide, conductive metallic oxide, silicon carbide, silicon oxide, aluminum oxide, and metallic boride, having a complex permittivity with a negative real part in the infrared region.

The metallic carbide may be selected from the group consisting of TiC and TaC.

The plasmonic reflector layer or the metallic total reflecting layer may be selected from the group consisting of TiN and TaN, having a complex permittivity with a negative real part.

The plasmonic reflector layer or the metallic total reflecting layer may be a transparent conductive oxide having a complex permittivity with a negative real part.

The plasmonic reflector layer or the metallic total reflecting layer may be composed of a material having a FOM of 1 or more.

A substrate may be arranged on the plasmonic reflector layer or the metallic total reflecting layer on the opposite side of the resonator layer, and the plasmonic reflector layer or the metallic total reflecting layer may be heated though the substrate.

The substrate or a surface of the substrate may be composed of a conductor having a resistance, and the substrate or the surface of the substrate may be heated by energizing the substrate.

The substrate may contain N-type doped SiC.

The plasmonic reflector layer or the metallic total reflecting layer may be energized to be heated.

### Advantageous Effects of Invention

The radiation light source according to the present invention may flexibly change wavelength widths of a thermal radiation spectrum by appropriately selecting the type of multi-layered structure and the thickness of each laminated film. Accordingly, it is possible to obtain an optimal radiation spectrum for heating according to the intended use or according to an absorption spectrum of an object to be heated. The radiation spectrum is narrower than radiation spectra of blackbody and graybody heaters in the related art. Accordingly, it is possible to decrease the temperature of an object to be processed during drying or heat processing and to reduce product damage caused by high temperature and to prevent ignition of vaporized solvents. In addition, the radiation light source according to the present invention has a simple multi-layered structure and does not require microfabrication by lithography and can be produced simply by film formation. Accordingly, it is possible to increase an area of a heater and to reduce cost.

When an oxide insulator or a high-temperature resistant insulator material such as SiC is employed in the outermost layer of the multi-layered distributed Bragg reflector, it is possible to prevent changes in refractive index and in structure due to oxidation during operation in the air at high temperatures up to 550° C. or about 600° C., preferably about 800° C., more preferably about 1000° C., and still more preferably even higher temperatures, which enables stable operation for a long period of time while reducing temperature dependence. The high-temperature resistance is a property which prevents changes in refractive index and in structure due to oxidation and does not affect repetitive operation of the multi-layered radiation light source according to the present invention in the air at the aforementioned temperature range, that is, 550° C. or about 600° C., preferably about 800° C., more preferably about 1000° C., and still more preferably even higher temperatures. Furthermore, employing an insulator as a material of the thin-film resonator prevents changes in optical conductivity due to thermal excitation and to prevent a resonant wavelength (radiation wavelength) from changing with temperature and with time. Still further, employing conductive ceramics such as high-melting-point plasmonic metals, alloys, metallic carbides, or metallic borides as a plasmonic material which constitutes a surface of the plasmonic reflector layer enables long-life operation at high temperatures. For applications in which directivity is required, such as in heating furnaces and sensors, a light emitting device can be implemented by setting the lamination cycle number for the distributed Bragg reflector to be three or more selecting a combination of materials of small and similar coefficients of thermal expansion and good adhesiveness from among metallic oxides, carbides, borides, and the like.

### BRIEF DESCRIPTION OF DRAWINGS

The left side of FIG. 1 shows examples of wavelength-selective radiation light sources in the related art that are two-dimensionally patterned by lithography. The right side of FIG. 1 shows typical radiation spectra of a radiation light source in a case using a metal disks/insulator/metal structure as shown in the top of the left side of the figure (Four different sizes of disks were produced. Each radiation spectrum of the device corresponds to each size. In each case, the pitch of the disks is 4.4 μm, and the insulator layer has a thickness of 200 nm. However, the sizes of the disks are increased from S3a (2.1 μm), S3b (2.5 μm), S3c (2.9 μm) to S3d (3.3 μm) in this order to set resonant wavelengths from 6.73 μm, 7.46 μm, 8.15 μm to 8.65 μm, respectively).

FIG. 2 shows an example of a high-temperature operable narrowband radiation light source with lamination of plasmonic reflector layer surface-insulator resonator layer-distributed reflector layer.

FIG. 3 shows exemplary structures (upper portion) and spectra (lower portion) of a high-temperature operable narrowband radiation light source with plasmonic reflector layer surface-insulator resonator layer-distributed reflector layer laminated.

FIG. 4 shows an exemplary structure (upper portion) and radiation angle dependence of radiation spectrum (lower portion) of a high-temperature operable narrowband radiation light source with plasmonic reflector layer surface-insulator resonator layer-distributed reflector layer laminated.

FIGS. 5(a) and 5(b) respectively show a real part and an imaginary part of a complex permittivity of LaB₆, or a plasmonic material usable at high temperatures. FIGS. 5(c) and 5(d) respectively show complex refractive indexes of Al₂O₃ and SiC, or insulator materials usable at high temperatures. FIGS. 5(a) and (b) show dependence of the permittivity with respect to a temperature of a base, using the base temperature during film formation as a parameter.

FIG. 6 is a view in which the moduli of values obtained by dividing real parts by imaginary parts of permittivities of various plasmonic materials are plotted, showing figure of merits (values in performance, abbreviated as FOM) of the plasmonic materials. At wavelengths around 700 nm or more, LaB₆ has the highest value among high-temperature resistant materials exclusive of Au, which indicates that LaB₆ is suitable as a thermal radiation light source material.

FIGS. 7(a)-(d) show examples of an operating principle and conceptual structures of a narrowband multi-layered radiation light source according to an embodiment of the present invention.

FIG. 7A shows calculation results of an electromagnetic field in the structure shown in FIG. 7(c).

FIGS. 8(a)-(c) show an exemplary structure of a radiation light source and absorptance of the radiation light source depending on incident angles for explaining fluctuations in radiation intensity of the narrowband multi-layered radiation light source depending on angles according to an embodiment of the present invention.

FIGS. 9(a)-(b) show reflection spectra and transmission spectra of a narrowband radiation light source having the structure shown in FIG. 8(c).

FIGS. 10(a)-(c) show conceptual structures of a radiation light source used in experiments in breakage of radiation light source structures when the narrowband multi-layered radiation light source according to an embodiment of the present invention is operated at high temperatures. FIGS. 10(a)-(c) also show radiation spectra using the temperatures of the structures as parameters. Herein, Ta, Mo and W are used as materials of a metallic total reflecting layer.

FIG. 11(a) shows an SEM image of a cross section of a radiation light source employing LaB₆ as a metallic total reflecting layer used in an experiment in breakage of radiation light source structures when the narrowband multi-layered radiation light source according to an embodiment of the present invention is operated at high temperatures. FIG. 11(b) shows radiation spectra using the temperature of the radiation light source as a parameter.

FIG. 12A shows SEM images of the radiation light source employing Ta as the metallic total reflecting layer which was employed in Example of the present invention and was broken by operation at a temperature over 810° C.

FIG. 12B shows SEM images of the radiation light source employing Mo as the metallic total reflecting layer which was employed in Example of the present invention and was broken by operation at a temperature over 900° C.

FIG. 12C shows SEM images of the radiation light source employing W as the metallic total reflecting layer which was employed in Example of the present invention and was broken by operation at a temperature over 860° C.

FIG. 12D shows SEM images of the radiation light source employing LaB₆ as the metallic total reflecting layer which was employed in Example of the present invention and was broken by operation at a temperature over 1100° C.

### DESCRIPTION OF EMBODIMENTS

A radiant structure employed in an embodiment of the present invention consists of three parts: a multi-layered distributed reflector layer (distributed Bragg reflector) having a structure in which insulator materials (or intrinsic semiconductors) having high-contrast refractive indexes are alternately laminated; a plasmonic reflector layer (plasmonic reflector (using, for example, Tamm plasmon)); and a resonator layer (thin-film resonator) consisting of an insulator (or an intrinsic semiconductor) sandwiched between the distributed reflector layer and plasmonic reflector layer. A heater (heat source) is in contact with the plasmonic reflector side, and the distributed Bragg reflector on the opposite side irradiates an object in the air (or in a vacuum). Hereinafter described are two typical device structures proposed in the present invention. Herein, a sharp or narrowband radiation peak is generated in what is called a photonic band gap. In order to make the photonic band gap wide to the possible extent, a difference in refractive index is increased between the alternately laminated materials in the distributed Bragg reflector.

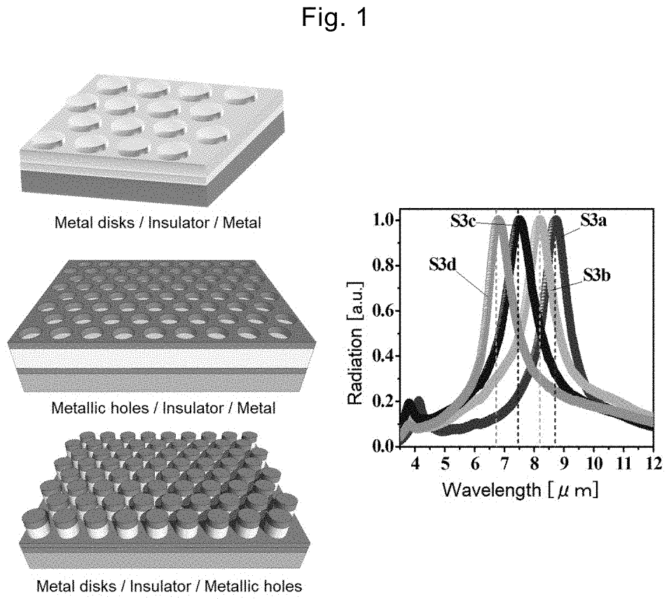

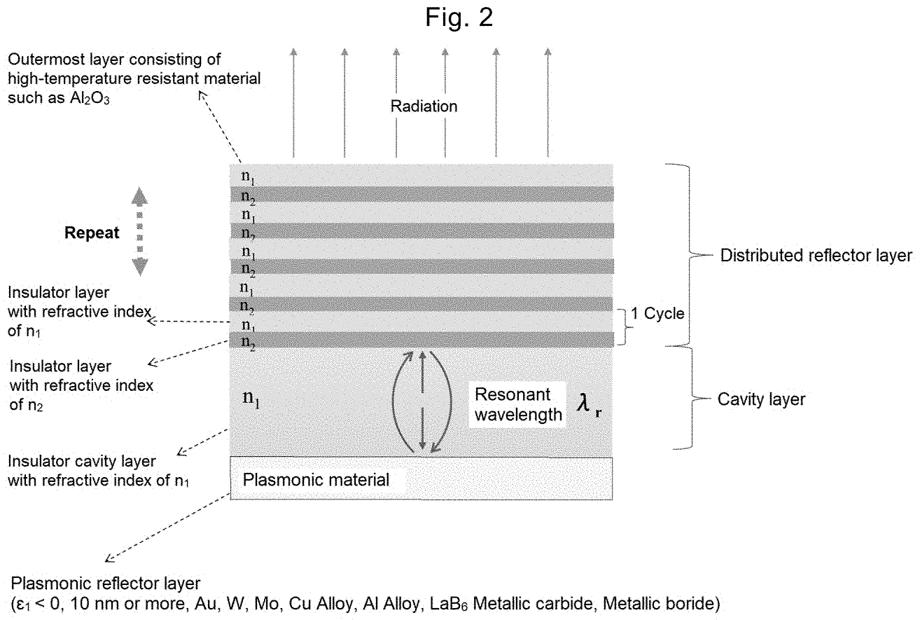

For example, as shown in FIG. 2, a structure that enables such a wide gap is provided with a plasmonic reflector layer (plasmonic reflector) consisting of a plasmonic material (metals, alloys, and conductive ceramics such as metallic carbides and metallic borides) disposed as the lowermost layer (on the side close to the heat source), a resonator layer (thin-film resonator) consisting of an insulator 1 with a refractive index of n₁ disposed on the plasmonic reflector layer, and a distributed reflector layer (distributed Bragg reflector) disposed on the resonator layer. In the distributed reflector layer, an insulator 2 with a refractive index n₂ which is substantially different from n₁ is disposed on the resonator layer, and these two types of insulators (insulator 1 and insulator 2) are laminated twice or more, and then, the insulator 1 is laminated lastly. Herein, the insulator 1 is a material such as Al₂O₃, SiO₂, or SiC that is resistant to oxidation at high temperatures.

The insulator on the uppermost layer (the side farthest from the heat source, that is, a surface of the distributed Bragg reflector facing an object to be irradiated) with the high-temperature resistance prevents changes in refractive index and in structure due to oxidation during high-temperature operation in the air and enables stable operation for a long period of time while reducing temperature dependence. For example, exposing LaB₆ to the air causes surface oxidation and changes in property at around 800° C. SiC shows no change of property up to a higher temperature of 1600° C. But when LaB₆ is buried under an alumina layer or the like, the inlying LaB₆ becomes resistant to high temperatures of 1000° C. and higher. Therefore, when a material having a particularly good high-temperature resistance is disposed in the uppermost layer or in several layers on the side close to the uppermost layer, a material with less high-temperature resistance can be used as inner layers. The same applies to the following other device structures.

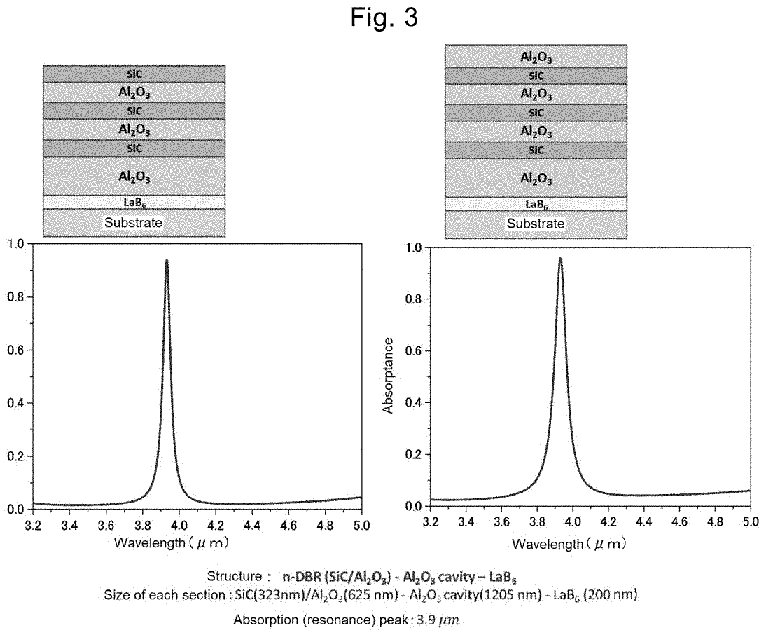

In the aforementioned device structure described with reference to FIG. 2, a thin-film material in the thin-film resonator (resonator layer) and a layer material in the multi-layered distributed Bragg reflector (distributed reflector layer) having a low refractive index are the same insulator (the insulator 1 such as Al₂O₃ and SiO₂). Accordingly, both have the same refractive index. However, note that the same material is used for simplification of film formation and that different materials may be used instead for the thin film and the layer. In practice, considering factors other than simplification of film formation, it is possible to appropriately determine whether to use the same material or different materials for the thin film and the layer. Specifically, in a second type of device structure schematically shown in FIG. 3, a high-melting-point plasmonic material is disposed as the lowermost layer (on the side close to a heat source). In a distributed Bragg reflector disposed above the plasmonic material, a resonator layer consisting of an insulator 1 is disposed, and then, an insulator 2 resistant to oxidation in the air is disposed on the insulator 1, and these two types of insulators are laminated repetitively. The resonator layer has a thickness equivalent to about half the desired radiation wavelength, and the insulator layers of the distributed Bragg reflector disposed above the resonator layer have a thickness (that is, the thickness of each layer consisting of the insulators) equivalent to about ¼ the desired radiation wavelength. The insulator 2 herein is a material having a refractive index substantially different from that of the insulator 1 and having resistance to oxidation at high temperatures. By repetitive electromagnetic field simulation, each layer is determined to have a thickness so that emissivity approaches 1, but each thickness usually deviates from the above values (half wavelength or ¼ wavelength) in the process of optimization. In the example shown in FIG. 1, the thickness of each layer is adjusted with Rsoft DIFFRACTMOD and MOST available from Synopsys Inc. In the device structure shown in FIG. 3, SiC and Al₂O₃, that is, materials of two types of layers that compose the distributed Bragg reflector, both have high-temperature oxidation resistance in the air. Accordingly, the top layer (outermost layer) may be either SiC (the left side in FIG. 3) or Al₂O₃ (the right side in FIG. 3).

In addition to the above structures, there is a third type of device structure. Instead of forming a film on a metal serving as a substrate, an infrared transparent insulator supporting substrate is disposed on the side close to a distributed Bragg reflector. In this case, the order of film formation is reversed. Examples of the infrared transparent substrate include sapphire (Al₂O₃) that transmits light with wavelengths from 0.3 to 6 μm, fused quartz substrate that transmits light with wavelengths from 0.2 to 3 μm, and ultralow-doped Si substrate that transmits light with wavelengths from 1.1 to 10 μm (for example, ultralow-doped Si wafer (50,000 Ωcm or more) grown by FZ method which is used for low-temperature operation at 200° C. or lower). On this transparent substrate, opposite to the aforementioned process, two types of insulator films are formed alternately, and after formation of a resonator layer, a plasmonic reflector layer is formed. This process may be followed by forming a film and other structures that perform various functions such as protection of the plasmonic reflector layer from chemical and physical influences during various processes after the film formation of the plasmonic reflector layer or during the actual use.

In any type of structure, the lowermost plasmonic reflector layer used herein has a high melting point of 1600° C. or higher, more preferably 2000° C. or higher, and has a permittivity with a negative real part in a wavelength band to be used and an imaginary part equal to or less than the modulus of the real part of the permittivity. Furthermore, it is more preferable that a material used herein should have a small coefficient of thermal expansion.

To describe further about the high-melting-point material (high-temperature resistant material, or heat resistant material), the radiation light source according to the present invention is usually desired to have resistance to high temperatures, but in practice, it is often the case that resistance to about 800° C. is enough. However, as a result of experiments (to be described), the inventors have found that even when a melting point of a material used in the radiation light source is raised above the upper limit of the operating temperature of the radiation light source, it is not enough to satisfy this condition. Through actual use, the inventors have found that the radiation light source is broken at a temperature far below the melting point. From this result and the known fact that a surface or an interface generally starts to melt at about two thirds of a melting point of a bulk, the inventors have derived a specific condition on the melting point of the aforementioned high-temperature resistant metal. Note that this material may be not only a single element metal but also a heat-resistant alloy or the like which has resistance to the aforementioned high temperatures and does not cause breakage of the radiation light source structure.

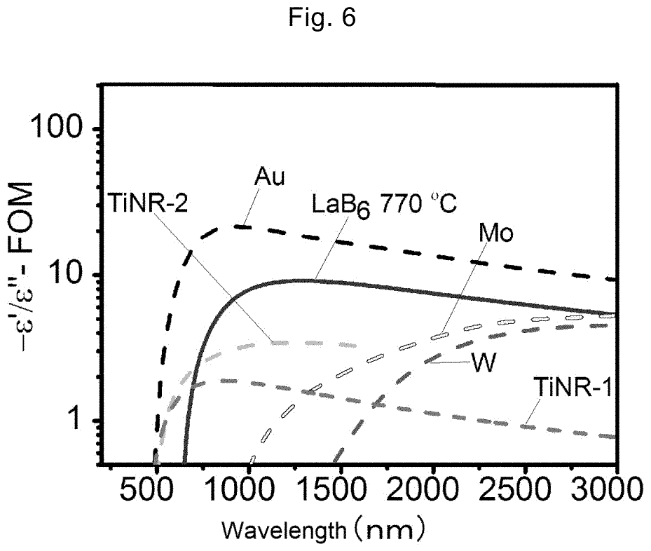

Furthermore, as shown in FIG. 6, at wavelengths of about 700 nm or more, LaB₆ has the highest value among high-temperature resistant materials exclusive of Au. From the aspect of FOM, Au is the best, but from the aspect of melting point, Au has a melting point of about 1064° C. (detachment from Si and SiO₂ or surface melt starts at about 350° C.) which is not that high. In addition, Au is extremely soft and is not exactly optimal as a thermal radiation light source material exposed to high temperatures. Compared to Au, LaB₆ has a FOM close to that of Au and has resistance to higher temperatures than Au. Accordingly, LaB₆ is highly desirable as a thermal radiation light source material. As can be seen from FIG. 6, it is preferable that a material of the plasmonic reflector layer should have a FOM of 1 or more at wavelengths around an absorption peak. More preferably, the material of the plasmonic reflector layer should have a FOM of 2 or more, and still more preferably, 5 or more. It is preferable to use metallic borides, carbides, and heat-resistant alloys that satisfy such conditions.

In FIG. 6, data associated with materials other than LaB₆ are drawn from the following existing literatures.
TiNR-1: Non-Patent Literature 4
TiNR-2: Non-Patent Literature 5
Au: Non-Patent Literature 6
Mo: Non-Patent Literature 7
W: Non-Patent Literature 8

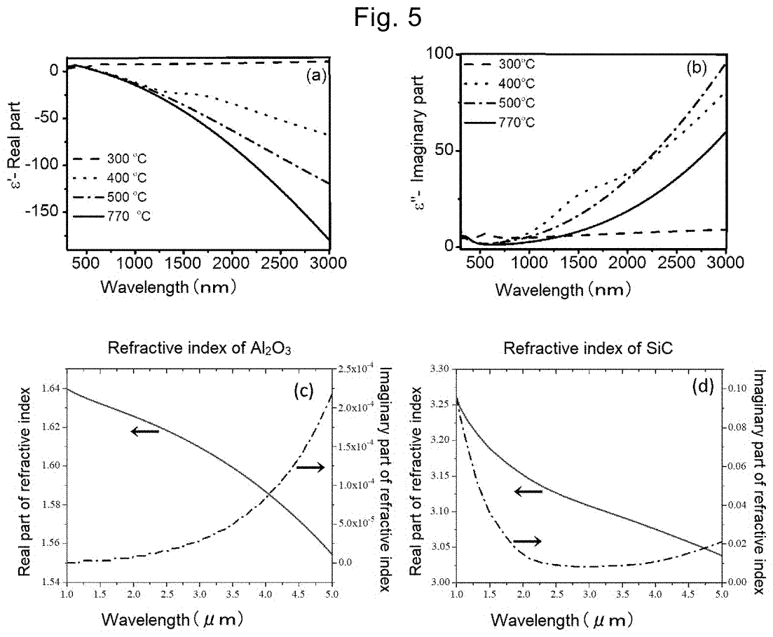

In regard to the insulator layers that compose the distributed reflector layer and the resonator layer, it is preferable to select materials having a large real part of a permittivity and a small imaginary part of the permittivity as can be seen from FIGS. 5(a)-(d). This is to prevent the loss to the possible extent. It is desirable that a complex refractive index should have an imaginary part of 0.2 or less. With respect to the refractive indices of the insulator layers, for example, silica has a mid-infrared refractive index of about 1.4, alumina has a mid-infrared refractive index of about 1.6, and Si₃N₄ has a mid-infrared refractive index of 1.8. These materials may also be employed as the insulator layer with a low refractive index. Known examples of the high-refractive index material include Si (mid-infrared refractive index is 3.4), Ge (mid-infrared refractive index is 4.0), and AlSb (mid-infrared refractive index is 3.6). These materials may be employed, but a preferable example is SiC which is operable at higher temperatures. When Si is employed as the high-refractive index material, for example, the material can be used as a PVD film comprising, as a raw material, ultralow-doped Si (50,000 Ωcm or more) grown by FZ method. In addition to these materials, for example, Ta₂O₅, Nb₂O₅, and HfO₂ are employable as the high-refractive index material. Particularly, the use of a material with resistance to high-temperature oxidation in the air as the outermost layer enables stable operation at high temperatures for a long period of time. In any case, it is preferable that a difference in refractive index of the insulator layers to be laminated be about 30% to 40% or more (in other words, the higher refractive index should be about 1.3 to 1.4 times the lower refractive index). Herein, “narrow band” is defined as a wavelength band at which Q value, or a value obtained by dividing a radiation wavelength by a half width of the radiation wavelength, is 30 or more. However, optimization based on such a structure makes it possible to achieve a structure having a narrowband radiation spectrum with Q value of about 40 or more as shown in FIG. 3. Furthermore, an oxide film or the like used in the insulator layers may be formed by PVD such as sputtering, CVD, and the sol-gel method. Still further, the insulator layers or the plasmonic reflector layer can be generally formed by an appropriate method such as PVD, CVD, PLD, and the sol-gel method depending on materials specifically used in the insulator layers or the plasmonic reflector layer.

As a result of further study, the inventors of the present application have found that the aforementioned plasmonic reflector layer may not be associated with plasmon polaritons and will do as long as the plasmonic reflector layer generally shows metallic properties. Therefore, the inventors have found that the above description of the invention of the present application is valid even when the term “plasmonic” is replaced with the term “metallic”. The following description uses the term “metallic” which is a broader concept.

Note that the term “metallic” or “plasmonic” materials herein not only refers to what is called metals, that is, metals and alloys of single elements but also refers to materials having optical metallic properties, or materials having a complex permittivity with a negative real part. For example, aforementioned LaB₆ is usually regarded as ceramics, but LaB₆ is one of the typical examples of metal since it has a complex permittivity with a negative real part in a wide wavelength range. Furthermore, the metal herein does not have to show a negative real part of the complex permittivity at all wavelengths but at least at a wavelength of interest, specifically, a peak when the device operates as a narrowband radiation light source. In other words, herein, “plasmonic material”≡“optical metal”≡“material having free carriers and a negative permittivity”. Still further, non-plasmonic materials are also employable since those materials perform as optical metals. For example, as will be described, SiO₂ has a region where the real part of the permittivity becomes negative in a narrow wavelength range of 8 to 9 μm which is close to an absorption wavelength of an optical phonon. Other types of materials also show a similar phenomenon in a particular wavelength range. This indicates that a dielectric exhibits the same physical behavior (produces resonant polarization) as the plasmonic material or metallic material herein at around a frequency of an optical phonon of a polar material. The present invention may also employ such a material in a broad sense as a substitute material for metal at a specific wavelength. The principle of the present invention will now be generally described below.

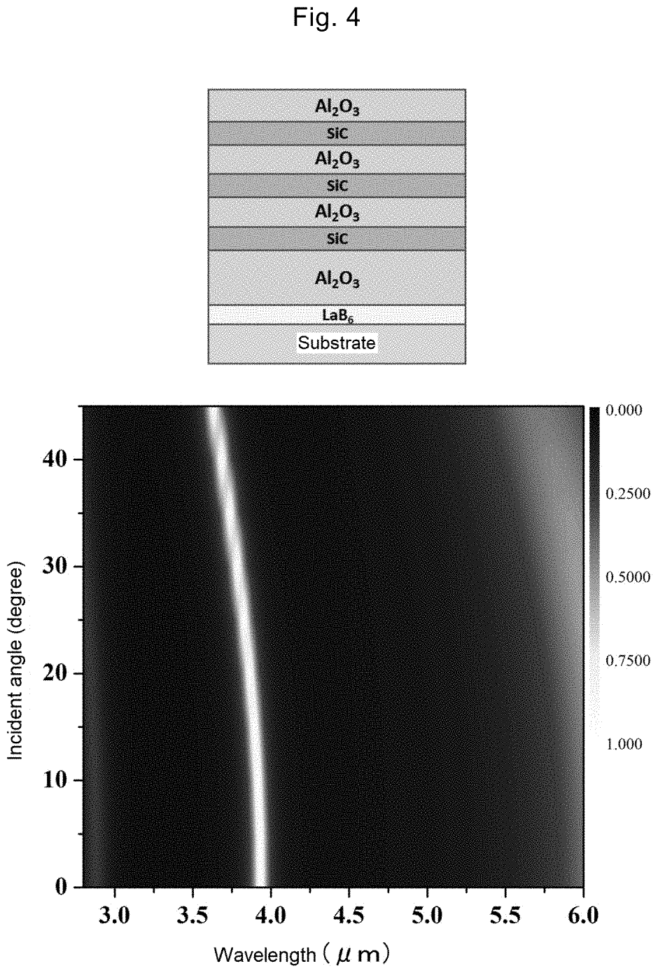

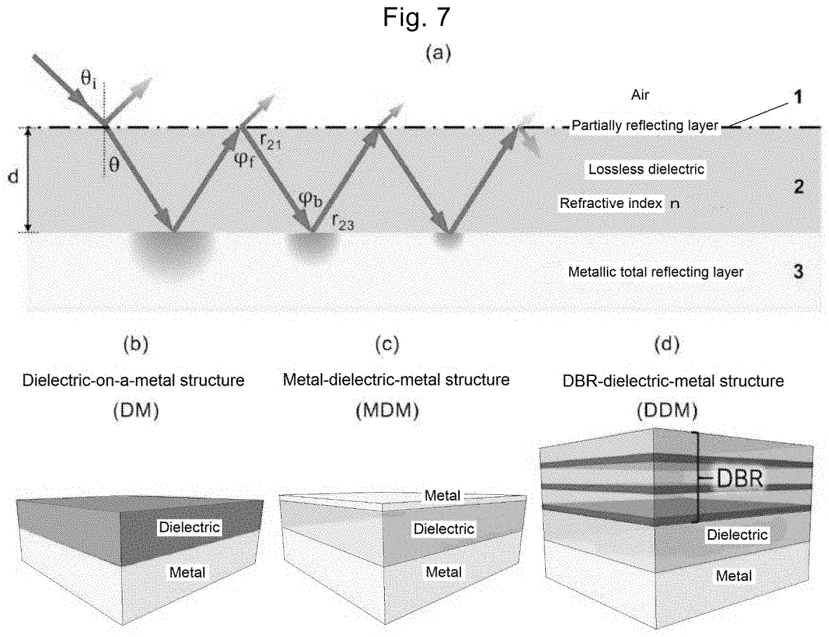

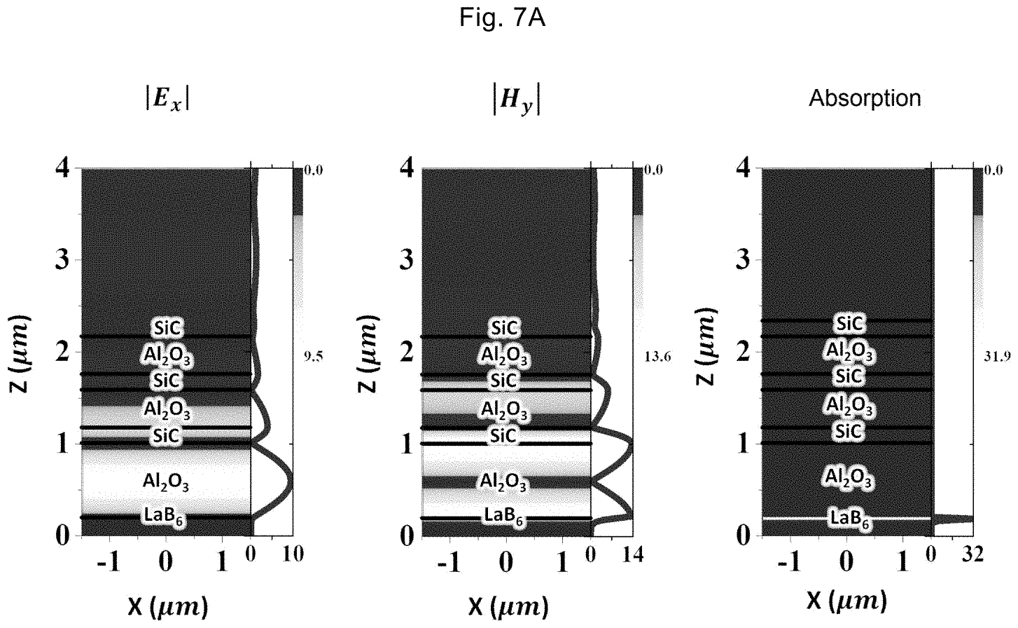

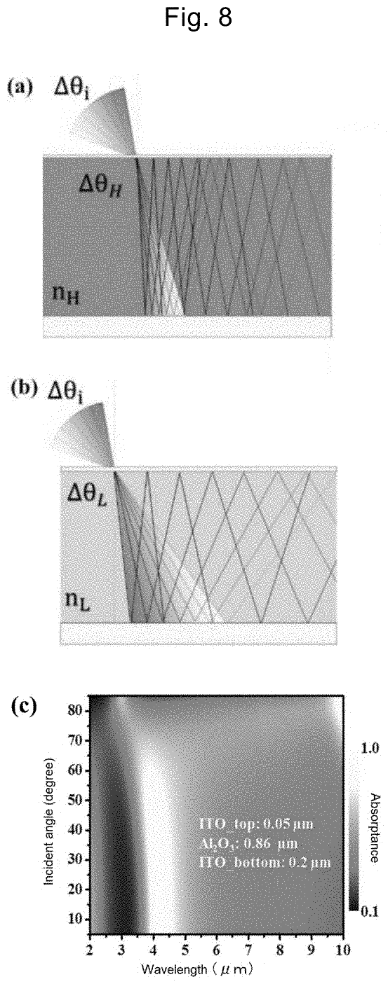

A typical embodiment of the present invention includes three types of narrowband radiation light source devices. All of these examples have a mechanism of wavelength control by the same physical origin called Gires-Tournois interferometer. As can be seen from FIGS. 7(a)-(d), in these radiation light source devices, two reflection layers face each other with an insulator resonator layer sandwiched therebetween. One of the reflection layers is a sufficiently thick total reflecting layer, and the other reflection layer on the opposite side is a partially reflecting layer that partially transmits light. The partially reflecting layer may be any of a dielectric-air interface that merely causes Fresnel reflection (FIGS. 7(a) and 7(b)). Note that the term “interface” herein is also defined as a type of layer.), a partially reflecting layer (FIG. 7(c)) with a metal thin enough to partially transmit light, or a distributed Bragg reflector (distributed reflector layer) formed as a multi-dielectric-layered structure (FIG. 7(d), which has the same structure as in FIGS. 2 to 4). As shown in FIG. 7(a), when light enters from the partially reflecting layer, the incident light is totally reflected by the total reflecting layer and then further reflected by the partially reflecting layer. Repeating this reflection gradually absorbs and attenuates the light while causing multiple reflections inside the resonator layer. This structure is basically the same as the Gires-Tournois interferometer and operates as an interferometer. Accordingly, when the incident light has a wavelength equal to a resonant wavelength of this interferometer, the number of multiple reflections and the strength of an electric field in the resonator layer are maximized, leading to complete absorption. Therefore, combination of this multi-layered structure with a pyroelectric material or the like makes it possible to achieve, for example, a wavelength-selective light receiving device that generates heat at a specific wavelength and electrically detects the wavelength. Furthermore, according to Kirchhoff's law of thermal radiation, heating this structure enables the device to operate as a narrowband radiation light source configured to perform narrowband radiation opposite to absorption properties. Accordingly, heating this structure enables the device to operate as a narrowband radiation light source configured to perform narrowband radiation opposite to absorption properties. Note that the structure shown in FIG. 7(d) enables higher wavelength resolution and is suitable for applications that require directivity since the resonant wavelength changes significantly with respect to the angle (see FIG. 4). On the other hand, in a case where directivity brings disadvantages, it is possible to lower the directivity in the structure shown in FIG. 7(c) by increasing the refractive index of the resonator layer (see the following description with reference to FIG. 8).

Furthermore, when an intensity distribution of an electric field as a result of the multiple reflections is close to the total reflecting layer, electric charges in the metal vibrate violently, which increases the degree of Joule heat due to the loss. However, when the center of distribution of the electric field is far from the metallic section, the loss is reduced, causing a narrow band. All layers may have a thickness changed from the Gires-Tournois structures shown in FIGS. 7(a)-(d) and optimized to generate multiple reflections while satisfying this condition. More specifically, FIG. 7A shows calculation results of the electromagnetic field in the structure shown in FIG. 7(d). In the figure, the depth direction of the device (the thickness direction of the layer) is taken along the ordinate, and the direction parallel to the layer surface is taken along the abscissa. The center of distribution of the electric field Eₓ is inside the dielectric. Since the dielectric has almost no loss (imaginary part of the dielectric function ε′≈0), the Joule loss becomes small and the resonance becomes sharp (resonance width becomes narrow). On the other hand, when the electric field distribution approaches the metal, the resonance width becomes broad because the Joule loss due to charge vibrations in the metal is large (ε′ is large). Adjusting the thickness of each layer in this manner makes it possible to adjust the electric field distribution and the width of a spectrum. In the structure shown in FIG. 7(b), when a resonant wavelength of the resonator layer is intentionally brought close to a lossy frequency such as a phonon frequency of the dielectric, it is possible to raise absorptance close to 1, which enables high absorption and high radiation with a simple two-layer structure.

FIGS. 8(a)-(c) show other examples of structures of the radiation light source according to the present invention in relation to operational properties of the radiation light source according to the present invention. In these structures, for example, as metallic layers, aforementioned LaB₆, a heat-resistant alloy (high-temperature resistant alloy), and ITO are disposed adjacent to both sides of a dielectric resonator layer. FIGS. 8(a) and 8(b) are schematic views respectively showing light paths when refractive indexes of the resonator layer are high (n_{H}) and low (n_{L}). The figures show that the resonator layer with a high refractive index (FIG. 8(a)) causes a small change in length of light path when light enters the resonator layer and causes a small change in resonant wavelength depending on angles. In other words, the higher the refractive index of the resonator layer, the more the dispersion of the resonant wavelength is reduced relative to the incident angle. That is to say, in this case, it is possible to radiate an intended specific wavelength in a wide angle. In a contrasting situation, the resonator layer with a low refractive index causes a large change in resonant wavelength depending on angles, which brings about a broad radiation spectrum. The former structure with a large refractive index enables uniform and narrowband heating of a planar large-area object. Furthermore, when the former structure is applied to a wavelength selective light receiving device, it is possible to detect incident light from a wide angle. FIGS. 8(a) and 8(b) show operation properties of the radiation light source in which the degree of change in resonant frequency depending on angles is affected by variations of the refractive index of the resonator layer. It should be noted that the operation properties described herein is not limited to the structures shown in the figures, and the same applies to various other structures as shown in FIGS. 7(a)-(d).

In some cases, window glass or the like requires a material that is transparent to visible light and has a high heat shield property. Adjusting various parameters of the configuration of the radiation light source according to the present invention makes it possible to increase absorption in a wavelength region, which greatly contributes to temperature rise in a room or the like in the infrared region. Accordingly, the structure of the present invention can be directly used for this type of heat shield.

Hereinafter described are typical values of refractive indexes, real parts of complex permittivity (the larger this value is on the negative side, the better the performance), melting points, and coefficients of thermal expansion in regard to typical materials to be used in the present invention. Note that there are still other materials included in the present invention other than the following materials. When values are not known or are informed but significantly different between several results, the values are considered to be unreliable. In such cases, the values are described as “(unknown)”.
SiO₂: Refractive index is 1.39 at a wavelength of 3 μm, real part of permittivity ε′=−4 at a wavelength of 9 μm, melting point is 1700° C., coefficient of thermal expansion is 0.6×10⁻⁶ K⁻¹
Si: Refractive index is 3.4 at a wavelength of 3 μm, melting point is 1414° C., coefficient of thermal expansion is 2.6×10⁻⁶ K⁻¹
Ge: Refractive index is 3.9 at a wavelength of 3 μm, melting point is 938° C., coefficient of thermal expansion is 6.0×10⁻⁶ K⁻¹
AlSb: Refractive index is 3.2 at a wavelength of 3 μm, melting point is 1060° C., coefficient of thermal expansion is 4.2×10⁻⁶ K⁻¹
Al₂O₃: Refractive index is 1.77 at a wavelength of 3 μm, real part of permittivity ε′=−36 at a wavelength of 22 μm, melting point is 2072° C., coefficient of thermal expansion is 7.2×10⁻⁶ K⁻¹
SiC: Refractive index is 2.6 at a wavelength of 3 μm, real part of permittivity ε′=−100 at a wavelength of 12 μm, melting point is 2730° C., coefficient of thermal expansion is 4.4×10⁻⁶ K⁻¹
Si₃N₄: Refractive index is 1.8 at a wavelength of 3 μm, melting point is 1900° C., coefficient of thermal expansion is 3.0×10⁻⁶ K⁻¹
LaB₆: ε′=−250 (metal) at a wavelength of 3 μm, melting point is 2210° C., coefficient of thermal expansion is 7.2×10⁻⁶ K⁻¹
Au: ε′=−747 (metal) at a wavelength of 3 μm, melting point is 1064° C., coefficient of thermal expansion is 14.2×10⁻⁶ K⁻¹
Ag: ε′=−486 (metal) at a wavelength of 3 μm, melting point is 962° C., coefficient of thermal expansion is 18.9×10⁻⁶ K⁻¹
Al: ε′=−869 (metal) at a wavelength of 3 μm, melting point is 660° C., coefficient of thermal expansion is 23.1×10⁻⁶ K⁻¹
Cu: ε′=−464 (metal) at a wavelength of 3 μm, melting point is 1085° C., coefficient of thermal expansion is 16.5×10⁻⁶ K⁻¹
W: ε′=−163 (metal) at a wavelength of 3 μm, melting point is 3422° C., coefficient of thermal expansion is 4.5×10⁻⁶ K⁻¹
Mo: ε=−276 (metal) at a wavelength of 3 μm, melting point is 2623° C., coefficient of thermal expansion is 4.8×10⁻⁶ K⁻¹
Ta: ε′=−291 (metal) at a wavelength of 3 μm, melting point is 3713° C., coefficient of thermal expansion is 6.3×10⁻⁶ K⁻¹
W: ε′=−163 (metal) at a wavelength of 3 μm, melting point is 3422° C., coefficient of thermal expansion is 4.5×10⁻⁶ K⁻¹
Ir: ε′=−69 (metal) at a wavelength of 3 μm, melting point is 2446° C., coefficient of thermal expansion is 6.4×10⁻⁶ K⁻¹
Pt: ε′=−99 (metal) at a wavelength of 3 μm, melting point is 1768° C., coefficient of thermal expansion is 8.8×10⁻⁶ K⁻¹
TiN: ε′=−182 (metal) at a wavelength of 3 μm, melting point is 2930° C., coefficient of thermal expansion is 8.8×10⁻⁶ K⁻¹

(In addition to TiN, metallic nitrides such as TaN are also employable.)
TiAl: ε′=(unknown) at a wavelength of 3 μm, melting point is 1460° C., coefficient of thermal expansion is 10.8×10⁻⁶ K⁻¹
NiAl: ε′=−105 (metal) at a wavelength of 3 μm, melting point is 1682° C., coefficient of thermal expansion is 12.5×10⁻⁶ K⁻¹ (The real part of the complex permittivity is obtained by, for example, ab initio calculation by the inventors of the present application.)
stainless steel: ε′=(unknown) at a wavelength of 3 μm, melting point is from 1300 to 1500° C., coefficient of thermal expansion is 11×10⁻⁶ K⁻¹
Indium tin oxide (ITO): ε′=−10 (metal) at a wavelength of 3 μm, melting point is from 1500 to 1900° C., coefficient of thermal expansion is 7×10⁻⁶ K⁻¹

(In regard to TiAl and SUS430, the exact real parts of complex permittivities in the infrared region are unknown. However, TiAl and SUS430 are metals and have metallic properties. Accordingly, both materials are employable for the metallic total reflecting layer of the narrowband multi-layered radiation light source according an embodiment of the present invention. In regard to the values of indium tin oxide, indium oxide accounts for 90% by weight, and tin oxide accounts for 10% by weight. In addition to ITO, conductive metallic oxides such as tungsten oxide and molybdenum oxide are also employable.)

Alternatively, a simplified structure may be used in which the distributed Bragg reflector (distributed reflector layer) and the thin-film resonator (resonator layer) are combined into one section to form a structure of about two or three layers laminated by combining materials with high refractive index contrast. Furthermore, as already described, instead of the distributed Bragg reflector, the air (more precisely, a dielectric-air interface that simply causes Fresnel reflection; and of course, an interface between the dielectric and other gases or vacuum) or a metallic partially reflecting layer may be disposed.

Still further, the radiant structure according to the present invention may be formed on a surface of a high heat-resistant semiconductor material such as N-type doped SiC, and the SiC may be electrically energized and heated to a high temperature. Alternatively, the radiant structure according to the present invention may be formed on a heat-resistant insulating substrate such as alumina or Si₃N₄, and an electric current may be flowed through the metallic total reflecting layer of the radiant structure to heat the substrate.

The radiation light source according to the present invention emits light by heating but can suppress light having a wavelength unnecessary for heating a product. Accordingly, it is possible to offer the prospect of saving energy used for the entire radiation. In addition, when the light source is heated with the same input power as a blackbody light source that emits broadband light, the total amount of radiation energy is smaller than that of the blackbody light source. Accordingly, it is possible to hold the temperature of the light source element high and to emit light with higher intensity than the blackbody light source at a resonant wavelength of the light source. The greatest feature of the radiation light source according to the present invention is that the radiation light source enables large-area, inexpensive, and stable operation even at high temperatures, and the radiation light source is of vital use to a practical large-area and high-intensity light source. Furthermore, the radiation light source irradiates a product of interest to the necessary extent, which can prevent unwanted temperature rise and deterioration by heat. This enables highly accurate molding or drying and opens the way to a new highly accurate production process. Still further, the radiation light source has a sharp radiation wavelength band. Accordingly, it is possible to selectively excite or selectively avoid specific molecular vibrations with high accuracy, leading to a new production process in which products are produced while being accurately processed and synthesized according to desired chemical bonds, molecular structures, or reactions. Similarly, it is possible to produce a light source that emits infrared light in a narrowband corresponding an absorption band of a chemical bond of a specific gas or vibration of a molecular species. Taking advantage of this potential, it is possible to achieve, for example, a compact and high-performance infrared light source that requires no filter and has a simple structure, and it is highly probable that such an infrared light source is applied to a small and highly accurate NDIR sensor component.

Note that the radiation light source according to the present invention is not only operable in high-temperature regions such as 550° C. or higher but also sufficiently effective in lower temperature regions. For example, the radiation light source according to the present invention inherently emits light in a plane, which is convenient for heating a large-area object. Surface emission is feasible even with the structure in the related art shown in FIG. 1, but the structure in FIG. 1 has an uneven structure with disks or holes and is irregular along an emission surface of the radiation light source. On the other hand, the radiation light source according to the present invention has an even structure along the surface, that is, a seamless regular layer which is simple and easy to produce. Moreover, since the radiation light source according to the present invention has the aforementioned seamless regular layer structure, it is possible to prevent an atmosphere where the radiation light source is used to penetrate into the interior of the metallic layer that is easily corroded or oxidized. Accordingly, the radiation light source has resistance superior to the structure shown in FIG. 1 with respect to environments where the disks or holes are easily penetrated by atmosphere gas or easily contaminated. Still further, it is necessary to control an emission spectrum according to a resonant wavelength of an absorption spectrum of an object to be processed or according to a width of the resonant wavelength. In such a case, the radiation light source according to the present invention can simply control the emission spectrum by adjusting film thicknesses during lamination (that is, for example, the deposition time of film formation). Accordingly, it is possible to design and control the emission spectrum more easily than a method using a metamaterial or a diffraction grating that requires microfabrication.

### EXAMPLES

FIG. 2 shows an example of a typical structure for carrying out the radiation light source according to the present invention. The lower side of FIG. 3 shows exemplary absorptance spectra for structures shown on the upper side of FIG. 3. Note that absorptance is equal to emissivity.

As a metallic total reflecting layer, LaB₆, that is, a material having a small thermal expansion and having a permittivity with a largely negative real part and a small imaginary part in the infrared wavelength band is laminated with a thickness of 100 nm or more, and on the layer of LaB₆, a resonator layer consisting of Al₂O₃ (Al₂O₃ cavity) is formed with a thickness of 1205 nm. On the resonator layer, a SiC layer with a thickness of 323 nm and an Al₂O₃ layer with a thickness of 625 nm are repetitively laminated. The lower left side of FIG. 3 shows simulation results of infrared reflection spectrum and absorption spectrum of a radiation light source having this multi-layered structure (herein, since the transmittance is zero, (absorptance)=1−(reflectance)). According to Kirchhoff's law of radiation, absorptance is equivalent to emissivity. Therefore, the absorption spectrum in this figure is equal to the emissivity spectrum. The figure shows that this structure has s sharp infrared radiation peak with a half width of 50 nm at 4 μm, emissivity of 0.94, and Q value of about 80. Furthermore, in this structure, as shown in FIG. 4, a resonant wavelength of absorption (or radiation) changes depending on angles. However, taking advantages of this feature, it is possible to achieve a sensor that changes detection wavelengths depending on incident angles or a high-directive light source that adjusts radiation wavelengths depending on radiation angles.

Hereinafter described is a method for producing a radiation light source for carrying out the present invention.

First, materials having a small coefficient of thermal expansion such as glass, quartz, alumina, Si, W, Mo, Ta, AlN, Si₃N₄, and Fernico alloys were used as a substrate material in contact with a heat source, and then, on the substrate, metallic conductive materials having high melting points and small coefficients of thermal expansion such as W, Mo, LaB₆, TiC, and TiN were formed into mirror-like films as a metallic total reflecting layer. W and Mo were deposited by DC sputtering with an electron beam evaporation device manufactured by ULVAC or i-Miller (CFS-4EP-LL) manufactured by Shibaura Mechatronics Corporation.

Film formation of LaB₆ was performed with an electron beam evaporation device manufactured by Eiko Corporation (revised EB350), under a base pressure in the range of 10⁻⁸ Pa (that is, 1×10⁻⁸ Pa or more and less than 1×10⁻⁷ Pa) and under a pressure during vapor deposition in the range of 10⁻⁶ Pa or less (that is, a pressure of 10⁻⁶ Pa or lower pressures) so as to set a deposition rate to about 3.5 nm/sec. A target of vapor deposition was changed to a single crystal prepared by FZ from a sintered compact prepared by vacuum hot pressing, which yielded a higher performance LaB₆ film (ε′=−250 at a wavelength of 3 μm). When the hot-pressed sintered compact was used as the target, good metallic properties were obtained by setting the base temperature during the film formation to about 740° C. to 800° C. (see FIGS. 5(a) and 5(b)).

On the other hand, in pulsed laser deposition (PLD), a real part of a permittivity was positive, and a film with metallic properties could not be formed (a pressure during vapor deposition was 5×10⁻⁵ Pa or less, a film formation temperature was 800° C., and a deposition rate was 0.004 nm/sec). Since a LaB₆ film known in the related art did not show such metallic properties or, if not at all, showed quite poor metallic properties, LaB₆ could not be used in reality as the metallic total reflecting layer of the narrowband multi-layered radiation light source according to an embodiment of the present invention. However, the inventors of the present application have found that a LaB₆ film prepared by the aforementioned method shows a FOM almost equivalent to that of Au in the infrared region, as already described with reference to FIG. 6. What is more, considering that the narrowband multi-layered radiation light source according to an embodiment of the present invention is required to have resistance to high temperatures such as 550° C., 600° C. or higher, the LaB₆ film with high metallic properties achieved first by the inventors of the present application is fairly preferable for use in the present invention. Generally speaking, a material used for the metallic total reflecting layer preferably has a FOM of 1 or more, more preferably 2 or more, and still more preferably 5 or more.

More specifically, in a case where a LaB₆ film is used as an example, a preferable FOM is 1 or more as described above. In addition, a LaB₆ film formed by the novel film formation method found by the inventors has a higher FOM and shows better properties than many other materials having metallic properties. Accordingly, the LaB₆ film can have a more preferable FOM of 2 or more. As also found by the inventors, in the novel film formation method, it is possible to achieve a higher FOM with single crystal LaB₆ instead of using a hot-pressed sintered compact as a LaB₆ target. In this case, an even more preferable FOM is 5 or more.

Film formation of TiN was performed by PLD at a pressure of 5×10⁻⁶ Pa or less during vapor deposition and a deposition rate of 0.01 nm/sec or more, whereby obtaining a good metallic film.

Plasmon materials such as W and Mo have high adhesion to ceramics at high temperatures. These materials also have a small coefficient of thermal expansion. Accordingly, these materials are preferable in that a difference in coefficient of thermal expansion is small when a film of the materials is formed on a material with a small coefficient of thermal expansion such as AlN, Si₃N₄, and Fernico alloys, which causes small thermal stress at an interface. Alternatively, a plate material of Mo or W having a mirror-finished surface on one side may double as the substrate and the metallic total reflecting layer.

On a surface of the metallic total reflecting layer, an insulator with good adhesion and a relatively low refractive index such as Al₂O₃ or SiO₂, or an insulator with a high refractive index such as SiC or high-purity Si is formed as a resonator layer. On this resonator layer, a distributed reflector layer having alternately changed refractive indexes is periodically arranged to form the structure shown in FIG. 2 or 3. It is preferable to combine materials having a large difference in refractive index: for example, SiO₂ and SiC or Al₂O₃ and SiC. The outermost layer is desirably Al₂O₃ or SiC resistant to oxidation in the air even at high temperatures. These insulator films were formed by RF sputtering with i-Miller (CFS-4EP-LL) manufactured by Shibaura Mechatronics Corporation. FIGS. 5(a)-(d) show results of optical properties of the formed materials measured with a spectroscopic ellipsometer.

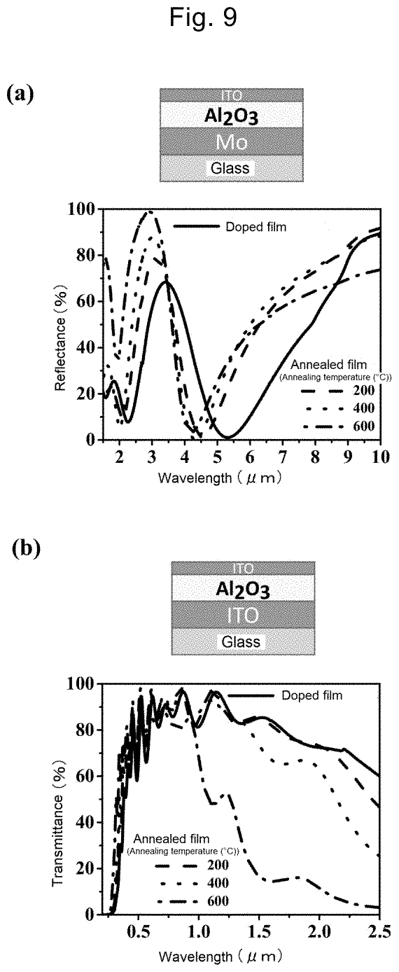

Hereinafter described are Examples of the radiation light source described with reference to FIGS. 8(a) and 8(b). Produced was a radiation light source in which ITO was used as two metallic reflection layers and alumina was used as a resonator layer (FIG. 8(c)). FIG. 8(d) shows measurement results of absorptance of this radiation light source. As can be seen from the figures, this radiation light source hardly changes in wavelength at which absorptance reaches a peak in an incident angle range of 0 to 60 degrees, that is, resonant wavelength. The angular dispersion of the absorptance being as small as this level indicates that the angular dispersion of the radiation (changes in radiation intensity depending on radiation directions (angles)) is also small according to Kirchhoff's law. Therefore, the radiation light source is a device suitable for large-area heat processing. FIGS. 9(a) and 9(b) respectively show reflection spectra and transmission spectra when the radiation light source with the structure shown in FIG. 8(c) is held at 23° C. and annealed at 200° C. to 700° C. FIG. 9(a) shows large dip in the reflectance spectra at wavelengths around 2.0 to 3.0 μm, indicating that this structure has high absorptance, or high emissivity, in this wavelength band. The transmittance spectra in FIG. 9(b) show that this structure has high transmittance in the visible band and low transmittance in the infrared region. The transmission bandwidth can be adjusted by adjusting physical properties of ITO, for example, by forming gas annealing in a diluted hydrogen gas atmosphere. Such feature indicates that this structure is suitable as a heat-shield coating such as a heat-shield window material and, generally, as a heat shield. Not only ITO but also transparent conductive oxides such as tungsten oxide, Al, or Ga-doped ZnO, and wide-gap metallic nitrides and carbides are employable as such a radiation light source and heat shield.

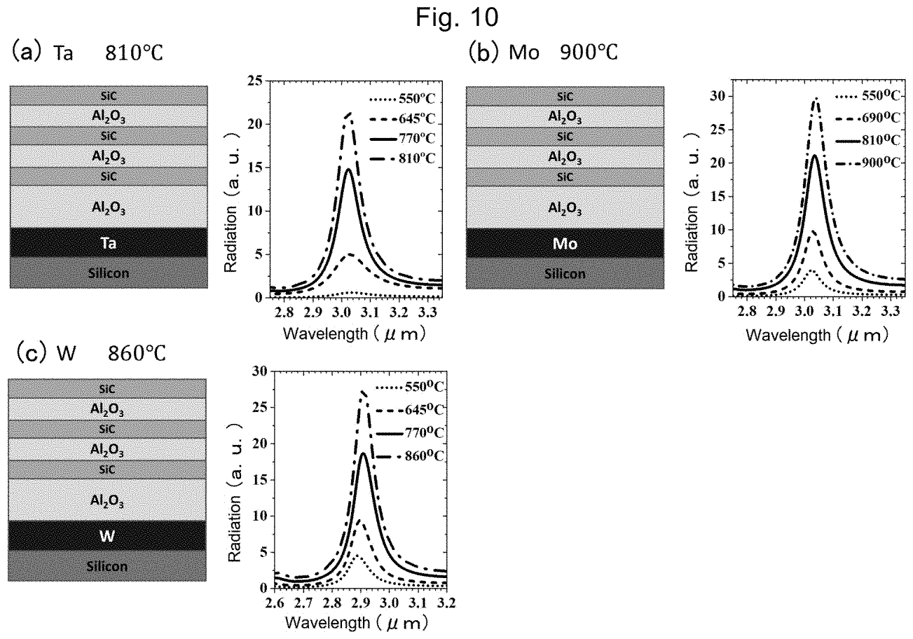

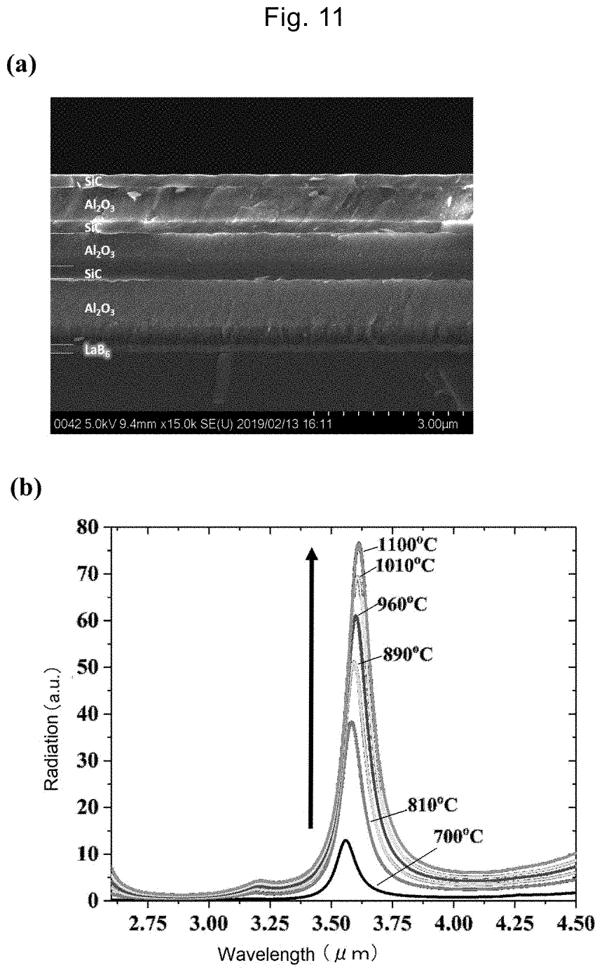

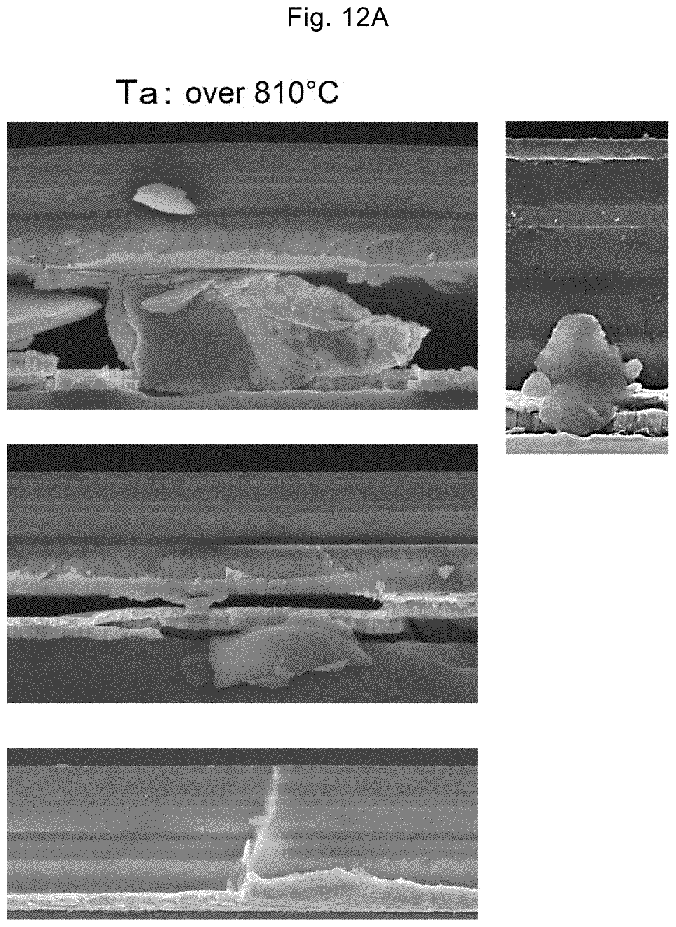

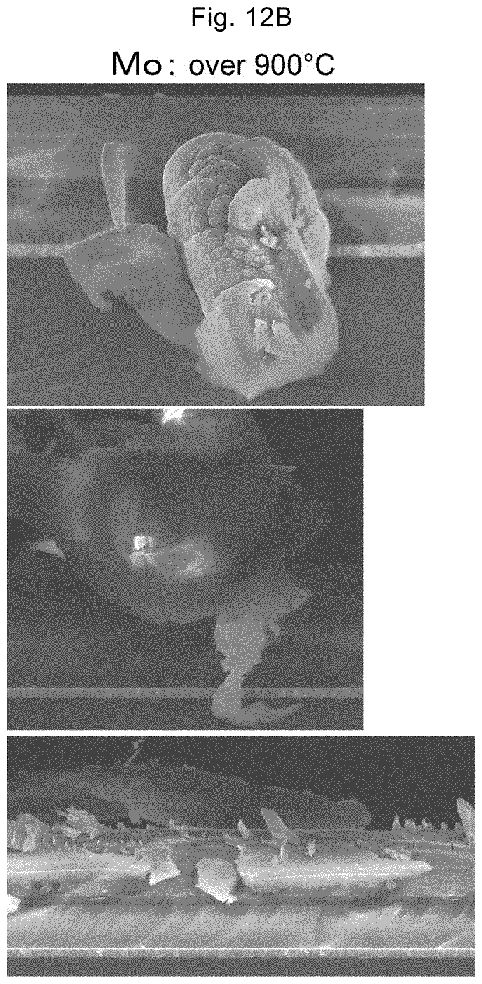

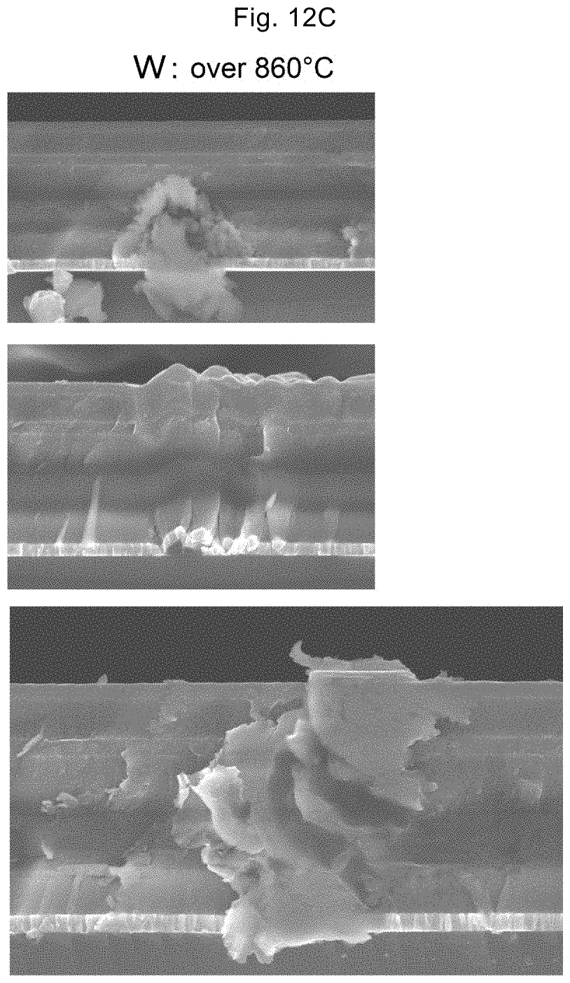

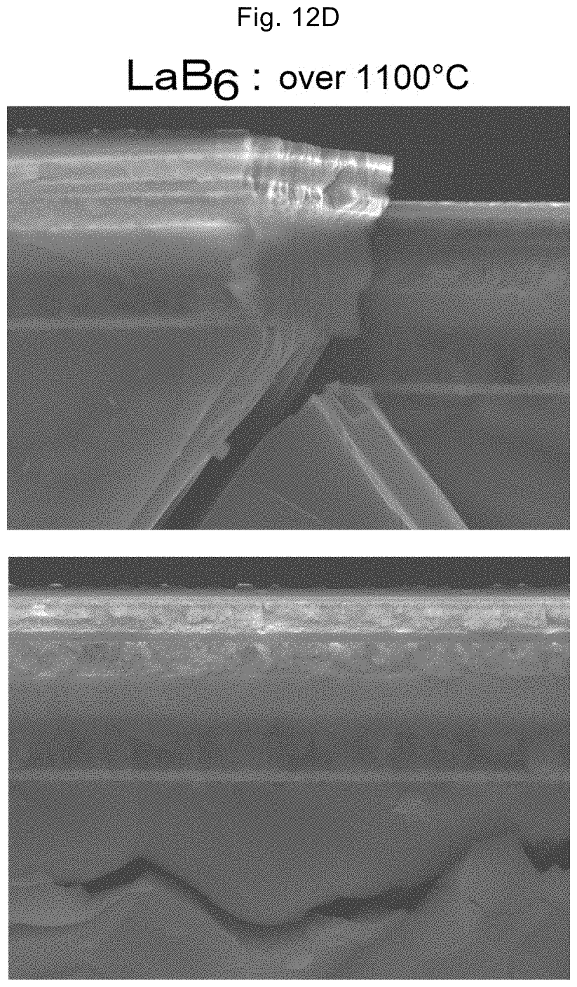

Furthermore, breakage experiments were conducted on radiation light source structures when the radiation light source according to the present invention was used at high temperatures. Specifically, radiation light sources having the structures shown in FIGS. 10(a)-(c) were produced and made to operate at temperatures higher than 800° C., followed by examination of destruction temperatures. As the radiation light source structures, employed were structures each including the aforementioned distributed Bragg reflector with SiC layers and Al₂O₃ layers laminated alternately and including Ta, Mo, W, or LaB₆ as a heat-resistant material of the metallic total reflecting layer on a silicon substrate. Among these radiation light sources, FIGS. 10(a) to 10(c) show conceptual cross-sectional views of the radiation light sources including Ta, Mo, and W, respectively, and also show radiation spectra using the temperatures of the radiation light sources as parameters. FIGS. 11(a)-(b) show a cross-sectional photograph of the radiation light source using LaB₆ as a material of the metallic total reflecting layer and also shows radiation spectra using the temperature of this radiation light source as a parameter. Operating temperatures of the radiation light sources are shown at the top of the spectra in each graph. Note that these spectra were measured at temperatures slightly lower than the temperatures at which the radiation light source structures were broken. FIGS. 12A to 12D show SEM images of the radiation light sources broken by operating the radiation light sources at temperatures over these operating temperatures. FIG. 12D shows the breakage of the radiation light source when LaB₆ was used as a material of the metallic total reflecting layer. In this condition, it is noteworthy that the place where cracks and distortions were actually shown at a temperature over 1100° C. was not the light source but Si serving as the base which has low heat resistance and that, if a high heat-resistant material is used as the base, there is still a possibility that the radiation light source can be used at higher temperatures without the base being broken. An example of such a base includes, but is not limited to, a thin film comprising Si₃N₄, SiC, or AlN. These materials enhance heat-resistance and heat-insulating properties of the base, which enables a radiation light source with better properties than a radiation light source including a Si base.

### CITATION LIST

### Patent Literature

Patent Literature 1: JP 4214178 B2

Patent Literature 2: JP 2015-114497 A

Patent Literature 3: JP 5867810 B2

### Non-Patent Literature

Non-Patent Literature 1: H. Sai, H. Yugami, Y Akiyama, Y. Kanamori, and K. Hane, Journal of the Optical Society of America A, Vol. 78, No. 2 (2001), 1471-1476.

Non-Patent Literature 2: Ivan Celenovic, David Perreault, John Kassakian, “Resonatly-cavity Enhanced Thermal Emission,” Physical Review B 72, 075127 (2005).

Non-Patent Literature 3: Zih-Ying Yang, Satoshi Ishii, Takahiro Yokoyama, Thang Duy Dao, Mao-Guo Sun, Pavel S. Pankin, Ivan V. Timofeev, Tadaaki Nagao, Kuo-Ping Chen. “Narrowband Wavelength Selective Thermal Emitters by Confined Tamm Plasmon Polaritons,” ACS PHOTONICS. 4 [9], 2212(2017).

Non-Patent Literature 4: Appl. Phys. Lett. 2017, 110 (10), 101901.

Non-Patent Literature 5: ACS Photonics, 2018, 5 (3), pp 814-819.

Non-Patent Literature 6: Olmon, R. L.; Slovick, B.; Johnson, T. W.; Shelton, D.; Oh, S.-H.; Boreman, G. D.; Raschke, M. B., Optical dielectric function of gold. Phys. Rev. B 2012, 86, 235147.

Non-Patent Literature 7: Ordal, M. A.; Bell, R. J.; Alexander, R. W.; Newquist, L. A.; Querry, M. R., Optical properties of Al, Fe, Ti, Ta, W, and Mo at submillimeter wavelengths. Appl. Opt. 1988, 27, 1203-1209.

Non-Patent Literature 8: Rakic, A. D.; Djurisic, A. B.; Elazar, J. M.; Majewski, M. L., Optical properties of metallic films for vertical-cavity optoelectronic devices. Appl. opt. 1998, 37, 5271-5283.

1. A multi-layered radiation light source comprising
a plasmonic reflector layer,
a resonator layer consisting of an insulator layer, said resonator layer being disposed adjacent to the plasmonic reflector layer, and
a distributed reflector layer having a structure in which a plurality of types of insulator layers having different refractive indexes are alternately laminated, said distributed reflector layer being disposed on the resonator layer on the opposite side of the plasmonic reflector layer,
wherein the multi-layered radiation light source emits an infrared light from the distributed reflector layer to the outside by heating the plasmonic reflector layer.

2. (canceled)

3. A multi-layered radiation light source comprising
a metallic total reflecting layer,
a resonator layer consisting of an insulator layer, said resonator layer being disposed adjacent to the metallic total reflecting layer, and
a partially reflecting layer being configured to reflect part of an incident light, said partially reflecting layer being disposed on the resonator layer on the opposite side of the metallic total reflecting layer,
wherein a metal in the metallic total reflecting layer is an optical metallic material having a complex permittivity with a negative real part at a wavelength to be used, and
wherein the multi-layered radiation light source emits an infrared light from the partially reflecting layer to the outside by heating the metallic total reflecting layer.

4. The multi-layered radiation light source according to claim 3, wherein the partially reflecting layer is an interface between the resonator layer and an external space formed by a surface of the resonator layer on the opposite side of the metallic total reflecting layer.

5. The multi-layered radiation light source according to claim 3, wherein the partially reflecting layer is a metallic layer which reflects part of an incident light.

6. The multi-layered radiation light source according to claim 5, wherein the metallic layer which reflects part of the incident light has high-temperature resistance.

7. The multi-layered radiation light source according to claim 3, wherein the partially reflecting layer is a distributed reflector layer having a structure in which a plurality of types of insulator layers having different refractive indexes are alternately laminated.

8. (canceled)

9. The multi-layered radiation light source according to claim 7, wherein the insulator layer which constitutes the resonator layer and the insulator layer having a lower refractive index in the distributed reflector layer are composed of the same material.

10. The multi-layered radiation light source according to claim 7, wherein the insulator layer which constitutes the resonator layer and the insulator layer having a lower refractive index in the distributed reflector layer are composed of different materials.

11. The multi-layered radiation light source according to claim 1, wherein, in the plurality of types of insulator layers which constitute the distributed reflector layer, the insulator layer having a higher refractive index has a refractive index 1.3 times or more a refractive index of the insulator layer having a lower refractive index.

12. The multi-layered radiation light source according to claim 1, wherein, in the plurality of types of insulator layers which constitute the distributed reflector layer, at least the insulator layer in contact with the air is composed of an oxide or SiC.

13. The multi-layered radiation light source according to claim 1, wherein, in the distributed reflector layer, the insulator layer having a lower refractive index is a material selected from the group consisting of SiO₂, Al₂O₃, and Si₃N₄, and the insulator layer having a higher refractive index is a material selected from the group consisting of Si, Ge, SiC, Ta₂O₅, Nb₂O₅, and HfO₂.

14. The multi-layered radiation light source according to claim 1, wherein the plasmonic reflector layer or the metallic total reflecting layer has high-temperature resistance.

15. The multi-layered radiation light source according to claim 1, wherein the plasmonic reflector layer or the metallic total reflecting layer is selected from the group consisting of LaB₆, Au, W, Mo, Cu alloy, Al alloy, and Ni alloy, having a complex permittivity with a negative real part, and from the group consisting of metallic nitride, metallic carbide, conductive metallic oxide, silicon carbide, silicon oxide, aluminum oxide, and metallic boride, having a complex permittivity with a negative real part in the infrared region.

16. The multi-layered radiation light source according to claim 15, wherein the metallic carbide is selected from the group consisting of TiC and TaC.

17. The multi-layered radiation light source according to claim 1, wherein the plasmonic reflector layer or the metallic total reflecting layer is selected from the group consisting of TiN and TaN, having a complex permittivity with a negative real part.

18. The multi-layered radiation light source according to claim 1, wherein the plasmonic reflector layer or the metallic total reflecting layer is a transparent conductive oxide having a complex permittivity with a negative real part.

19. The multi-layered radiation light source according to claim 1, wherein the plasmonic reflector layer or the metallic total reflecting layer is composed of a material having a FOM of 1 or more.

20. The multi-layered radiation light source according to claim 1,
wherein a substrate is disposed on the plasmonic reflector layer or the metallic total reflecting layer on the opposite side of the resonator layer, and
wherein the plasmonic reflector layer or the metallic total reflecting layer is heated though the substrate.

21. The multi-layered radiation light source according to claim 20, wherein the substrate or a surface of the substrate is composed of a conductor having a resistance, and the substrate or the surface of the substrate is heated by electrically energizing the substrate.

22. The multi-layered radiation light source according to claim 21, wherein the substrate contains N-type doped SiC.

23. The multi-layered radiation light source according to claim 1, wherein the plasmonic reflector layer or the metallic total reflecting layer is electrically energized to be heated.
